(19) United States
(12) Patent Application Publication
(10) Pub. No.: US 2025/0057019 A1
(43) Pub. Date: Feb. 13, 2025

(54) DISPLAY DEVICE AND METHOD OF MANUFACTURING DISPLAY DEVICE

(71) Applicant: Samsung Display Co., LTD., Yongin-si (KR)

(72) Inventors: HO LIM, Yongin-si (KR); GIHOON YANG, Yongin-si (KR)

(21) Appl. No.: 18/652,992

(22) Filed: May 2, 2024

(30) Foreign Application Priority Data
Aug. 8, 2023 (KR) 10-2023-0103572

(51) Int. Cl. H10K 59/80; H10K 59/12; H10K 59/38; H10K 102/00

(52) U.S. Cl. CPC H10K 59/877; H10K 59/1201; H10K 59/38; H10K 2102/331; H10K 2102/351

(57) ABSTRACT

A display device includes a substrate; a light-emitting device disposed on the substrate; a color conversion layer disposed on the light-emitting device; a color filter layer disposed on the color conversion layer; a first coating layer disposed on the color filter layer and including a scattering particle and a dispersion layer in which the scattering particle is dispersed; and a second coating layer disposed on the first coating layer and having a smaller refractive index than a refractive index of the first coating layer.

This application claims priority to Korean Patent Application No. 10-2023-0103572, filed on Aug. 8, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device, and more particularly to a display device that provides visual information and a method of manufacturing the display device.

### 2. Description of the Related Art

As information technology develops, the importance of display devices, which are a connecting medium between users and information, is emerging. For example, a use of liquid crystal display device (“LCD”), organic light-emitting display device (“OLED”), plasma display device (“PDP”), quantum dot display device is increasing. The use of display devices such as the like is increasing.

A matte display reduces light reflection and allows an image to be displayed without interference from sunlight or lighting. In the matte display, a matte film, or the like may be disposed on top of a display panel to implement a matte surface texture.

### SUMMARY

The disclosure may provide a display device with improved display quality.

The disclosure may provide a method of manufacturing the display device.

A display device in an embodiment of the disclosure includes a substrate, a light-emitting device disposed on the substrate, a color conversion layer disposed on the light-emitting device, a color filter layer disposed on the color conversion layer, a first coating layer disposed on the color filter layer and including a scattering particle and a dispersion layer in which the scattering particle is dispersed, and a second coating layer disposed on the first coating layer and having a smaller refractive index than a refractive index of the first coating layer.

In an embodiment, a refractive index of the scattering particle may be different from a refractive index of the dispersion layer.

In an embodiment, the scattering particle may include at least one of a silica particle, a hollow silica particle, an organic polymer particle, a metal oxide particle, a metal particle, a carbon particle, and a zeolite particle.

In an embodiment, the scattering particle has a size of about 0.2 micrometers or more and about 2 micrometers or less.

In an embodiment, a content of the scattering particle may be about 10 weight percent or more and about 80 weight percent of less.

In an embodiment, the second coating layer may include a silicon compound having the refractive index of less than about 1.5

In an embodiment, the second coating layer may include a material having a fluorine content of about 10 percent or more and a molecular weight of about 10,000 or more.

In an embodiment, the second coating layer may include a material having a hollow silica content of about 10 weight percent or more and about 80 weight percent or less, and a molecular weight of about 10,000 or more.

In an embodiment, a hollow silica particle of the hollow silica content may have a size of about 50 nanometers or more and about 400 nanometers or less.

In an embodiment, a thickness of the first coating layer may be greater than a thickness of the second coating layer.

In an embodiment, the second coating layer may have a thickness of about 80 nanometers or more and about 500 nanometers or less.

In an embodiment, the scattering particle may scatter and reflect specularly reflected light.

In an embodiment, the second coating layer may destructively interfere with specularly reflected light.

A method of manufacturing the display device in an embodiment of the disclosure includes forming a light-emitting device, a color conversion layer, and a color filter layer on a substrate sequentially; forming a first coating layer including a scattering particle and a dispersion layer in which the scattering particle is dispersed on the color filter layer; and forming a second coating layer having a smaller refractive index than a refractive index of the first coating layer on the first coating layer.

In an embodiment, the scattering particle is formed to have a size of about 0.2 micrometers or more and about 2 micrometers or less.

In an embodiment, a content of the scattering particle is about 10 weight percent or more and about 80 weight percent of less.

In an embodiment, the second coating layer includes a silicon compound having the refractive index of less than about 1.5

In an embodiment, the second coating layer includes a material having a fluorine content of about 10 percent or more and a molecular weight of about 10,000 or more.

In an embodiment, the second coating layer includes a material having a hollow silica content of about 10 weight percent or more and about 80 weight percent or less, and a molecular weight of about 10,000 or more.

In an embodiment, the second coating layer has a thickness of about 80 nanometers or more and about 500 nanometers or less.

As described above, in embodiments, a display device may include a substrate, a light-emitting device disposed on the substrate, a color conversion layer disposed on the light-emitting device, a color filter layer disposed on the color conversion layer, a first coating layer disposed on the color filter layer and including a scattering particle and a dispersion layer in which the scattering particle is dispersed, and a second coating layer disposed on the first coating layer and having a smaller refractive index than a refractive index of the first coating layer. Accordingly, a reflectance of the display device due to external light may be reduced. In Addition, a display quality of the display device may be improved.

In addition, by forming the coating layers in the display device, a manufacturing process of the display device may be simplified and a manufacturing cost may be reduced compared to a process of attaching an additional member.

### BRIEF DESCRIPTION OF THE DRAWINGS

Illustrative, non-limiting embodiments will be more clearly understood from the following detailed description in conjunction with the accompanying drawings.

FIG. 1 is a plan view of an embodiment of a display device.

FIG. 2 is a cross-sectional view taken along line I-I′ of FIG. 1.

FIG. 3 is a cross-sectional view illustrating the color conversion layer included in the display device of FIG. 2.

FIG. 4 is a cross-sectional view illustrating an embodiment of a coating layer included in the display device of FIG. 2.

FIG. 5 is a cross-sectional view illustrating another embodiment of a coating layer included in the display device of FIG. 2.

FIGS. 6, 7, and 8 are cross-sectional views illustrating a method of manufacturing the display device of FIG. 2.

### DETAILED DESCRIPTION

Embodiments of the disclosure now will be described more fully hereinafter with reference to the accompanying drawings, in which various embodiments are shown. Embodiments of the disclosure may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

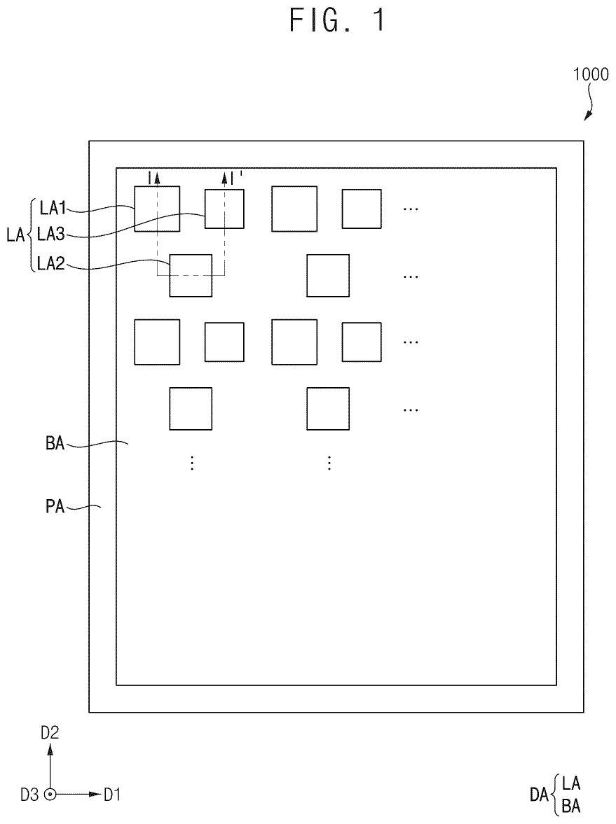

FIG. 1 is a plan view of an embodiment of a display device.

Referring to FIG. 1, a display device 1000 in an embodiment of the disclosure may include a display area DA and a peripheral area PA. The display area DA may be defined as an area that displays an image. The peripheral area PA may be defined as an area that does not display the image. The peripheral area PA may be disposed around the display area DA. In an embodiment, the peripheral area PA may surround an entirety of the display area DA, for example.

The display area DA may include a plurality of light-emitting areas LA and a light-blocking area BA. Each of the plurality of light-emitting areas LA may include a first light-emitting area LA1, a second light-emitting area LA2, and a third light-emitting area LA3.

Each of the first light-emitting area LA1, the second light-emitting area LA2, and the third light-emitting area LA3 may be an area where light emitted from a light-emitting device is emitted to an outside of the display device 1000. In an embodiment, first light may be emitted from the first light-emitting area LA1, second light may be emitted from the second light-emitting area LA2, and third light may be emitted from the third light-emitting area LA3, for example.

In an embodiment, the first light may be red light, the second light may be green light, and the third light may be blue light, for example. However, the disclosure is not limited thereto, and for example, in the first to third light-emitting areas LA1, LA2, and LA3, light of various colors such as yellow, cyan, and magenta may be emitted.

Four or more lights may be emitted from the first to third light-emitting areas LA1, LA2, and LA3. In an embodiment, the first to third light-emitting areas LA1, LA2, and LA3 may combined to emit at least one of the yellow, cyan, and magenta lights in addition to the red, green, and blue lights, for example. In addition, the first to third light-emitting areas LA1, LA2, and LA3 may be combined to emit more white light.

In a plan view, each of the first to third light-emitting areas LA1, LA2, and LA3 may be repeatedly disposed along row and column directions. Specifically, each of the first to third light-emitting areas LA1, LA2, and LA3 may be repeatedly disposed along a first direction D1 and a second direction D2 perpendicular to the first direction D1.

In an embodiment, the first light-emitting area LA1 and the third light-emitting area LA3 may be alternately disposed along the first direction D1 in odd rows (e.g., first row) of the display area DA, the second light-emitting area LA2 may be repeatedly disposed in the even rows (e.g., second row) adjacent to the odd row of the display area DA along the first direction D1, for example.

Areas of the first to third light-emitting areas LA1, LA2, and LA3 may be different from each other. In an embodiment, the area of the first light-emitting area LA1 that emits red light may be greater than each of the area of the second light-emitting area LA2 that emits the green light and the third light-emitting area LA3 that emits the blue light, for example. In this case, the area of the second light-emitting area LA2 may be greater than the area of the third light-emitting area LA3. However, the disclosure is not limited thereto. In an embodiment, the area of the second light-emitting area LA2 that emits the green light may be greater than each of the area of the first light-emitting area LA1 that emits the red light and the area of the third light-emitting area LA3 that emits the blue light. In this case, the area of the first light-emitting layer LA1 may be greater than the area of the third light-emitting layer LA3, for example.

Each of the first to third light-emitting areas LA1, LA2, and LA3 may have a triangular planar shape, a square planar shape, a circular planar shape, a track-shaped planar shape, an oval planar shape, or the like. In an embodiment, each of the first to third light-emitting areas LA1, LA2, and LA3 may have a quadrangular planar shape, e.g., rectangular planar shape, for example.

The light-blocking area BA may be disposed between the first to third light-emitting areas LA1, LA2, and LA3. In an embodiment, in the plan view, the light-blocking area BA may surround the first to third light-emitting areas LA1, LA2, and LA3, for example. The light-blocking area BA might not emit the light.

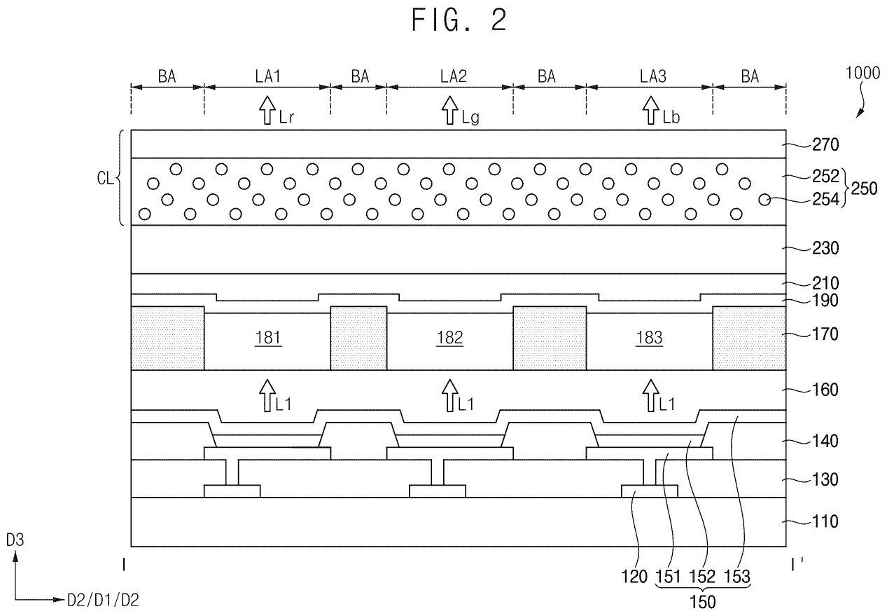

FIG. 2 is a cross-sectional view taken along line I-I′ of FIG. 1.

Referring to FIG. 2, the display device 1000 in an embodiment of the disclosure may include a substrate 110, a driver 120, an insulating structure 130, a pixel defining layer 140, a light-emitting device 150, an encapsulation structure 160, a bank layer 170, a color conversion layer 180, a capping layer 190, a low refractive index layer 210, a color filter layer 230, and a coating layer CL.

The display device 1000 may have a structure including the coating layer CL disposed on the one substrate 110.

The light-emitting device 150 may include a lower electrode 151, a light-emitting layer 152, and an upper electrode 153. The color conversion layer 180 may include a first color conversion pattern 181, a second color conversion pattern 182, and a transmission pattern 183. The coating layer CL may include a first coating layer 250 and a second coating layer 270.

The substrate 110 may include a transparent material or an opaque material. The substrate 110 may include or consist of a transparent resin substrate. In embodiments, the transparent resin substrate may include a polyimide substrate, or the like. In this case, the polyimide substrate 110 may include a first organic layer, a first barrier layer, a second organic layer, or the like. In an alternative embodiment, the substrate 110 may include a quartz substrate, a synthetic quartz substrate, a calcium fluoride substrate, a fluorine-doped quartz substrate, a soda-lime glass substrate, non-alkali glass substrate, or the like. These may be used alone or in any combinations with each other.

The driver 120 may be disposed on the substrate 110. In an embodiment, the driver 120 may include a thin film transistor, for example. In an embodiment, the driver 120 may include amorphous silicon, polycrystalline silicon, or a metal oxide semiconductor, for example.

The metal oxide semiconductor may include a binary compound (ABx), a ternary compound (ABₓCy), a four-component compound (ABₓC_{y}D_{z}), or the like including indium (In), zinc (Zn), gallium (Ga), tin (Sn), titanium (Ti), aluminum (Al), hafnium (Hf), zirconium (Zr), magnesium (Mg), or the like. In an embodiment, the metal oxide semiconductor may include zinc oxide (ZnOₓ), gallium oxide (GaOₓ), tin oxide (SnOₓ), indium oxide (InOₓ), indium gallium oxide (“IGO”), indium zinc oxide (“IZO”), and indium tin oxide. (“ITO”), indium zinc tin oxide (“IZTO”), indium gallium zinc oxide (“IGZO”), or the like, for example. These may be used alone or in any combinations with each other.

The insulating structure 130 may be disposed on the substrate 110. The insulating structure 130 may cover the driver 120. The insulating structure 130 may include a combination of at least one inorganic insulating layer and at least one organic insulating layer. In an embodiment, the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), or the like, for example. In addition, the organic insulating layer may include or consist of photoresist, polyacryl-based resin, polyimide-based resin, polyamide-based resin, siloxane-based resin, acryl-based resin, epoxy-based resin, or the like. These may be used alone or in any combinations with each other.

The lower electrode 151 may be disposed in each of the first to third light-emitting areas LA1, LA2, and LA3 on the insulating structure 130. The lower electrode 151 may be connected to the driver 120 through a contact hole defined by removing a portion of the insulating structure 130. In an embodiment, the lower electrode 151 may include metal, alloy, metal nitride, conductive metal oxide, transparent conductive material, or the like, for example. These may be used alone or in any combinations with each other. In an embodiment, the lower electrode 151 may act as an anode.

The pixel defining layer 140 may be disposed in the light-blocking area BA on the insulating structure 130 and the lower electrode 151. The pixel defining film 140 may cover opposite sides of the lower electrode 151 and may expose an upper surface of the lower electrode 151. The pixel defining layer 140 may include an organic material or an inorganic material. In an embodiment, the pixel defining layer 140 may include an organic material, for example. In embodiments, the organic material that may be used in the pixel defining layer 140 may include photoresist, polyacrylic resin, polyimide resin, polyamide resin, siloxane resin, acrylic resin, and epoxy resin, or the like. These may be used alone or in any combinations with each other.

The light-emitting layer 152 may be disposed on the lower electrode 151. In an embodiment, a hole provided from the lower electrode 151 and an electron provided from the upper electrode 153 may combine in the light-emitting layer 152 to form an exciton, and as the exciton change from an excited state to a ground state, the light may be emitted from the light-emitting layer 152, for example. The light-emitting layer 152 may emit the light having predetermined colors (e.g., red, green, and blue). In an embodiment, the light-emitting layer 152 may emit light (e.g., blue light) L1, for example.

The upper electrode 153 may be disposed on the light-emitting layer 152 and the pixel defining layer 140. The upper electrode 153 may be entirely disposed in the first to third light-emitting areas LA1, LA2, and LA3 and the light-blocking area BA. In an embodiment, the upper electrode 153 may include metal, alloy, metal nitride, conductive metal oxide, transparent conductive material, or the like, for example. These may be used alone or in any combinations with each other. In an embodiment, the upper electrode 153 may act as a cathode.

Accordingly, the light-emitting device 150 including the lower electrode 151, the light-emitting layer 152, and the upper electrode 153 may be disposed on the substrate 110. The light-emitting device 150 may be disposed in each of the first light-emitting area LA1, the second light-emitting area LA2, and the third light-emitting area LA3. The light-emitting device 150 may be electrically connected to the driver 120. In an embodiment, the light-emitting device 150 may include a blue light-emitting device that emits the light (e.g., blue light) L1.

The encapsulation structure 160 may be disposed on the upper electrode 153. The encapsulation structure 160 may prevent impurities, moisture, or the like from penetrating into the light-emitting device 150 from the outside. The encapsulation structure 160 may include at least one inorganic encapsulation layer and at least one organic encapsulation layer. In an embodiment, the inorganic encapsulation layer may include silicon oxide, silicon nitride, silicon oxynitride, or the like. These may be used alone or in any combinations with each other, for example. The organic encapsulation layer may include a cured polymer such as polyacrylate.

The bank layer 170 may be disposed on the encapsulation structure 160. The bank layer 170 may overlap the light-blocking area BA. The bank layer 170 may surround the color conversion layer 180. A space that may accommodate an ink composition may be defined in the bank layer 170 during a process of forming the color conversion layer 180. Accordingly, in the plan view, the bank layer 170 may have a grid shape or a matrix shape.

In an embodiment, the bank layer 170 may include an organic material such as epoxy resin, phenol resin, acrylic resin, silicone resin, or the like, for example. These may be used alone or in any combinations with each other.

In an embodiment, the bank layer 170 may further include a light-blocking material to serve as a black matrix, for example. In an embodiment, at least a portion of the bank layer 170 may further include a light-blocking material such as pigment, dye, carbon black, or the like, for example.

The color conversion layer 180 may be disposed on the encapsulation structure 160. The color conversion layer 180 may convert the light emitted from the light-emitting device 150 into the light having a predetermined wavelength.

As described above, the color conversion layer 180 may include the first color conversion pattern 181, the second color conversion pattern 182, and the transmission pattern 183. The first color conversion pattern 181 may overlap the first light-emitting area LA1, the second color conversion pattern 182 may overlap the second light-emitting area LA2, and the transmission pattern 183 may overlap the third light-emitting area LA3.

The first color conversion pattern 181 may convert the light L1 (e.g., the blue light) emitted from the light-emitting device 150 into the first color light Lr. The second color conversion pattern 182 may convert the light L1 emitted from the light-emitting device 150 into the second color light Lg. The transmission pattern 183 may transmit the light L1 emitted from the light-emitting device 150. In an embodiment, the first color may be red and the second color may be green, for example. In addition, the transmission pattern 183 may transmit the third color light (e.g., blue light) Lb. However, the disclosure is not limited thereto.

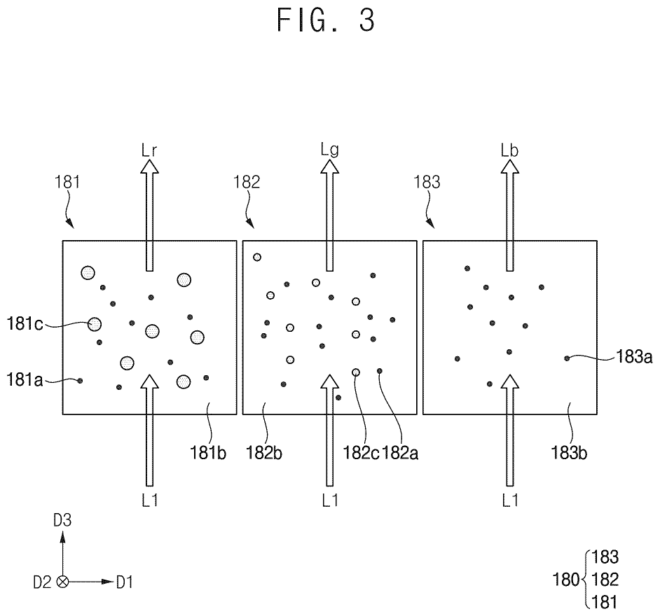

FIG. 3 is a cross-sectional view illustrating the color conversion layer included in the display device of FIG. 2.

Referring to FIGS. 2 and 3, the first color conversion pattern 181 may include a first quantum particles 181c that emitted the first color light Lr excited by the light L1 emitted from the light-emitting device 150. In addition, the first color conversion pattern 181 may further include a first photosensitive polymer 181b in which the first scattering particles 181a are dispersed.

The second color conversion pattern 182 may include a second quantum particles 182c that emitted the second color light Lg excited by the light L1 emitted from the light-emitting device 150. In addition, the second color conversion pattern 182 may further include a second photosensitive polymer 182b in which the second scattering particles 181a are dispersed.

The transmission pattern 183 may transmit the light L1 emitted from the light-emitting device 150 to emit the third color light (e.g., blue light) Lb. In addition, the transmission pattern 183 may include a third photosensitive polymer 183b in which third scattering particles 183a are dispersed.

In an embodiment, each of the first to third photosensitive polymers 181b, 182b, and 183b may include an organic material having light transparency, such as silicone resin, epoxy resin, or the like, for example. The first to third scattering particles 181a, 182a, and 183a may scatter and emit the light emitted from the light-emitting device 150. In addition, the first to third scattering particles 181a, 182a, and 183a may include a same material as each other.

Accordingly, the first color light Lr is emitted from the first light-emitting area LA1, the second color light Lg is emitted from the second light-emitting area LA2, and the third color light Lb is emitted from the third light-emitting area LA3 may be emitted.

Referring back to FIG. 2, the capping layer 190 may be disposed on the bank layer 170 and the color conversion layer 180. The capping layer 190 may be entirely disposed in the first to third light-emitting areas LA1, LA2, and LA3 and the light-blocking area BA. The capping layer 190 may serve as a moisture barrier to prevent deterioration of the color conversion layer 180.

In an embodiment, the capping layer 190 may be disposed along profiles of each of the bank layer 170 and the color conversion layer 180, for example. That is, the capping layer 190 may have a substantially uniform thickness along the profiles of each of the bank layer 170 and the color conversion layer 180. In another embodiment, the capping layer 190 may cover the bank layer 170 and the color conversion layer 180 on the bank layer 170 and the color conversion layer 180 and may have a flat top surface without forming a step around the bank layer 170 and the color conversion layer 180.

The capping layer 190 may include a silicon compound. In an embodiment, the capping layer 190 may include silicon oxide, silicon nitride, silicon oxynitride, or the like, for example. These may be used alone or in any combinations with each other.

The low refractive index layer 210 may be disposed on the capping layer 190. The low refractive index layer 210 may be disposed entirely in the first to third light-emitting areas LA1, LA2, and LA3 and the light-blocking area BA. The low refractive index layer 210 may have a relatively low refractive index. In an embodiment, a refractive index of the low refractive index layer 210 may be lower than a refractive index of the color conversion layer 180, for example. The low refractive index layer 210 may include an organic material. In an embodiment, the low refractive index layer 210 may include an organic polymer material including silicon, for example.

The color filter layer 230 may be disposed on the low refractive index layer 210. In an embodiment, the color filter layer 230 may include a light-blocking pattern and a color filter pattern, for example.

The light-blocking pattern may overlap the light-blocking area BA. The light-blocking pattern may provide a space to accommodate the ink composition during the process of forming the color filter pattern. Therefore, in the plan view, the light-blocking pattern may have a grid shape or a matrix shape.

The light-blocking pattern may prevent light leakage. In an embodiment, the light-blocking pattern may include an organic material such as epoxy resin, phenol resin, acrylic resin, silicone resin, or the like, for example. These may be used alone or in any combinations with each other.

In addition, the light-blocking pattern may further include a light-blocking material such as black pigment, black dye, carbon black, or the like. In an embodiment, the light-blocking pattern may be a black matrix, for example.

The color filter pattern may overlap each of the light-emitting areas (e.g., the first light-emitting area LA1, the second light-emitting area LA2, and the third light-emitting area LA3). In an embodiment, the color filter pattern may include a first color filter pattern, a second color filter pattern, and a third color filter pattern. The first color filter pattern may cut colors except the first color among the light passing through the first light-emitting area LA1, for example. The second color filter pattern may cut colors except the second color among the light passing through the second light-emitting area LA2. The third color filter pattern may cut colors except the third color among the light passing through the third light-emitting area LA3. However, the disclosure is not limited thereto.

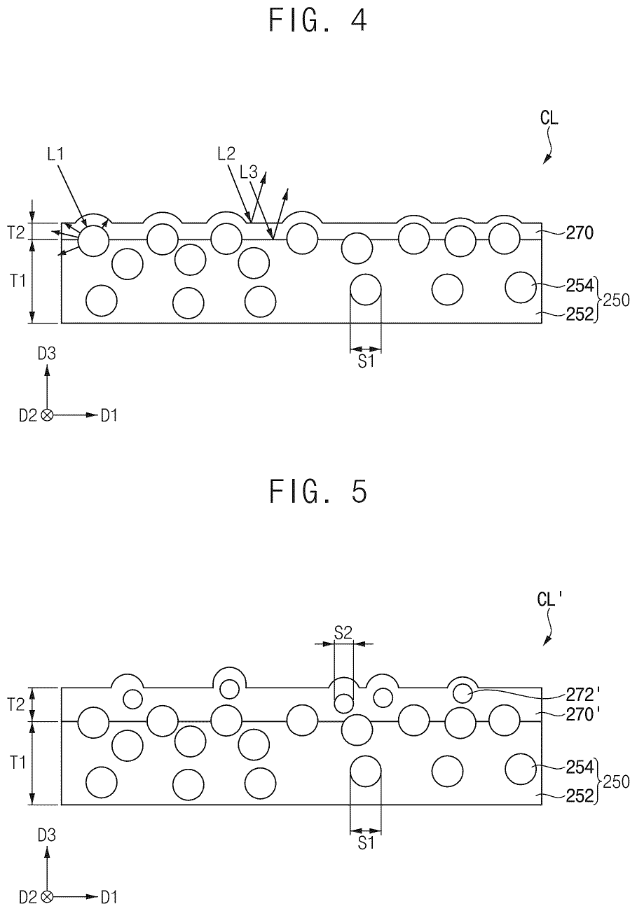

FIG. 4 is a cross-sectional view illustrating an embodiment of a coating layer included in the display device of FIG. 2.

Referring to FIGS. 2 and 4, the coating layer CL may be disposed on the color filter layer 230. The coating layer CL may include the first coating layer 250 and the second coating layer 270.

In an embodiment, the first coating layer 250 may be disposed on the color filter layer 230. The first coating layer 250 may be disposed entirely in the first to third light-emitting areas LA1, LA2, and LA3 and the light-blocking area BA. The first coating layer 250 may perform a surface flattening function and protect the driver 120, the light-emitting device 150, or the like from penetration of external air. In addition, the first coating layer 250 may remove the specularly reflected light through scattered reflection. The specular reflection (or glass reflection) may refer to reflected light with a same angle of incidence and reflection.

In an embodiment, the first coating layer 250 may include a dispersion layer 252 and scattering particles 254.

In an embodiment, the dispersion layer 252 may include an inorganic material and/or an organic material. In an embodiment, the dispersion layer 252 may include an acrylic resin, methacrylic resin, vinyl resin, epoxy resin, urethane resin, cellulose resin, perylene resin, silsesquioxane resin (e.g., polyhedral oligomer silsesquioxane (“POSS”)), or the like, for example. These may be used alone or in any combinations with each other. That is, the dispersion layer 252 may include a thermosetting material or a photocuring material. However, the disclosure is not limited thereto.

The scattering particle 254 may have a different refractive index from a material included in the dispersion layer 252 and may be a particle capable of scattering the light. In an embodiment, the scattering particle 254 may be a silica particle, a hollow silica particle, an organic polymer particle, a metal oxide particle, a metal particle, a carbon particle, a zeolite particle, or the like. These may be used alone or in any combinations with each other. However, the disclosure is not limited thereto. The scattering particle 254 may use various particles capable of scattering the light.

A size S1 of the scattering particle 254 may be more than about ¼ of the wavelength of light. In an embodiment, the size S1 of the scattering particle 254 may be about 0.2 micrometers (um) or more and about 2 micrometers (um) or less.

When the size of the scattering particle 254 is less than about 0.2 micrometers, the scattering reflection may be difficult.

When the size of the scattering particle 254 exceeds about 2 micrometers, a thickness of the dispersion layer 252 that disperses the scattering particle 254 may become thick. Accordingly, the thickness of the display device 1000 may also increase.

In an embodiment, a content of scattering particle 254 may be about 10 weight percent (wt. %) or more and about 80 weight percent (wt. %) or less. The content of the scattering particle 254 may mean a value expressed as a percentage of the weight of the scattering particle 254.

When an amount of the scattering particle 254 is less than about 10 weight percent, the scattering reflection may be difficult.

When the content of the scattering particle 254 exceeds about 80 weight percent, the scattering particle 254 may be difficult to disperse in the dispersion layer 252. Accordingly, a film characteristic of the first coating layer 250 might not be realized.

A thickness T1 of the first coating layer 250 may be about 3 micrometers or more and about 10 micrometers or less. Accordingly, the scattering particle 254 may be evenly dispersed in the dispersion layer 252.

However, the disclosure is not limited thereto.

In an embodiment, the second coating layer 270 may be disposed on the first coating layer 250. The second coating layer 270 may be disposed entirely in the first to third light-emitting areas LA1, LA2, and LA3 and the light-blocking area BA. The second coating layer 270 may remove specular reflected light through destructive interference.

In an embodiment, the second coating layer 270 may have a single-layer structure, for example. In this case, a target reflectance may be greater than a reflectance of the anti-reflective (“AR”) coating according to a comparative example. The “AR” coating according to the comparative example may be a coating that reduces reflectance using an optical interference phenomenon or reduces surface reflection through a silicon film including porous silica.

In an embodiment, the second coating layer 270 may include a silicon compound having a refractive index of less than about 1.5. Preferably, the second coating layer 270 may include a silicon compound having the refractive index of about 1.45 or less. In an embodiment, the second coating layer 270 may include silicon oxide, silicon nitride, silicon oxynitride, or the like, for example. These may be used alone or in any combinations with each other.

In an embodiment, the second coating layer 270 including the silicon compound may be formed through a chemical vapor deposition (“CVD”) process, for example. At this time, the refractive index may be adjusted by forming a porous in the second coating layer 270.

When the refractive index of the second coating layer 270 exceeds about 1.5, to induce the destructive interference may be difficult. The refractive index of the first coating layer 250 may be about 1.5. Therefore, when there is no difference in refractive index between the first coating layer 250 and the second coating layer 270, the destructive interference might not occur. Accordingly, reflected light may be visible in the display device 1000 and the display quality may deteriorate.

In an embodiment, the second coating layer 270 may include a polymer with a fluorine content of about 10% or more and a molecular weight of about 10,000 or more. In an embodiment, the second coating layer 270 may include an organic material substituted with fluorine and/or an inorganic material substituted with fluorine, for example. In an embodiment, the second coating layer 270 may include fluorinated-polysiloxane, fluorinated-polyurethane, fluorinated-polyurethane-acrylate, fluorinated polyhedral oligomer silsesquioxane, or the like, for example. These may be used alone or in any combinations with each other.

In an embodiment, when the fluorine content is less than about 10%, the refractive index of the second coating layer 270 may exceed about 1.5, for example. Accordingly, as described above, the reflected light may be visible in the display device 1000 and display quality may deteriorate.

When the molecular weight is less than about 10,000, a mechanical property (e.g., hardness, or the like) of the second coating layer 270 may be reduced. Accordingly, the mechanical property (e.g., durability, etc.) of the display device 1000 may deteriorate.

FIG. 5 is a cross-sectional view illustrating another embodiment of a coating layer included in the display device of FIG. 2.

Referring to FIGS. 2 and 5, a coating layer CL′ may be disposed on the color filter layer 230. The coating layer CL′ may include the first coating layer 250 and a second coating layer 270′.

The coating layer CL′ of FIG. 5 may differ from the coating layer CL of FIG. 4 only in a composition of the second coating layer 270′. Hereinafter, overlapping descriptions will be omitted or simplified.

In an embodiment, the first coating layer 250 may be disposed on the color filter layer 230 and the second coating layer 270′ may be disposed on the first coating layer.

In an embodiment, the second coating layer 270′ may further include a plurality of hollow inorganic particles 272′ dispersed therein. In an embodiment, each of the inorganic particles 272′ may include silica (SiO₂), magnesium fluoride (MgF₂), iron oxide (Fe₃O₄), or the like, for example. These may be used alone or in any combinations with each other.

In an embodiment, the second coating layer 270′ may include a polymer with a content of inorganic particles 272′ of about 10 weight percent or more and about 80 weight percent or less and a molecular weight of about 10,000 or more.

When the content of the inorganic particles 272′ is less than about 10 weight percent, the refractive index of the second coating layer 270′ may exceed about 1.5. Accordingly, as described above, the reflected light may be visible in the display device 1000 and the display quality may deteriorate.

When content of the inorganic particles 272′ exceeds about 80 weight percent, the mechanical property (e.g., the hardness, or the like) of the second coating layer 270′ may deteriorate. Accordingly, the mechanical property (e.g., the durability, or the like) of the display device 10000 may deteriorate.

In an embodiment, a size S2 of the inorganic particles 272′ included in the second coating layer 270′ may be about 50 nanometers or more and about 400 nanometers or less. A thickness T2 may be about 80 nanometers (nm) or more and about 500 nanometers (nm) or less.

When the thickness T2 of the second coating layer 270′ is less than about 80 nanometers or exceeds about 500 nanometers, the destructive interference might not occur. The size S2 of the inorganic particles 272′ may be affected by the thickness T2 of the second coating layer 270′. In an embodiment, the thickness T2 of the second coating layer 270′ may be smaller than the thickness T1 of the first coating layer 250, for example. Accordingly, the size S2 of the inorganic particles 272′ may be smaller than the size S1 of the scattering particles 254.

In a case of the display device according to the comparative example, a matte film may be disposed on a display panel. The matte film may be attached to the display panel using an adhesive (e.g., a pressure sensitive adhesive (“PSA”), or the like). In the case of the matte film, the manufacturing cost is more than twice that of the “AR” film. Accordingly, a process cost of the display device according to the comparative example including the matte film may be high.

However, the display device 1000 in an embodiment of the disclosure may include the substrate 110, the light-emitting device 150 disposed on the substrate 110, and the color conversion layer 180 disposed on the light-emitting device 150, the color filter layer 230 disposed on the color conversion layer 180, the first coating layer 250 disposed on the color filter layer 230 and including the scattering particle 254 and the dispersion layer 252 in which the scattering particle 254 are dispersed, the second coating layer 270 disposed on the first coating layer 250 and having the smaller refractive index than a refractive index of the first coating layer 250. Accordingly, the reflectance of the display device 1000 due to external light may be reduced. In addition, the display quality of the display device 1000 may be improved.

In the above, the display device 1000 of the disclosure is described as an organic light-emitting display device (“OLED”), but the disclosure is not limited thereto. In an embodiment, the display device 1000 may be a liquid crystal display device (“LCD”), a field emission display device (“FED”), a plasma display device (“PDP”), an electrophoretic display device (“EPD”), a quantum dot display device, an inorganic light-emitting display device, or the like, for example.

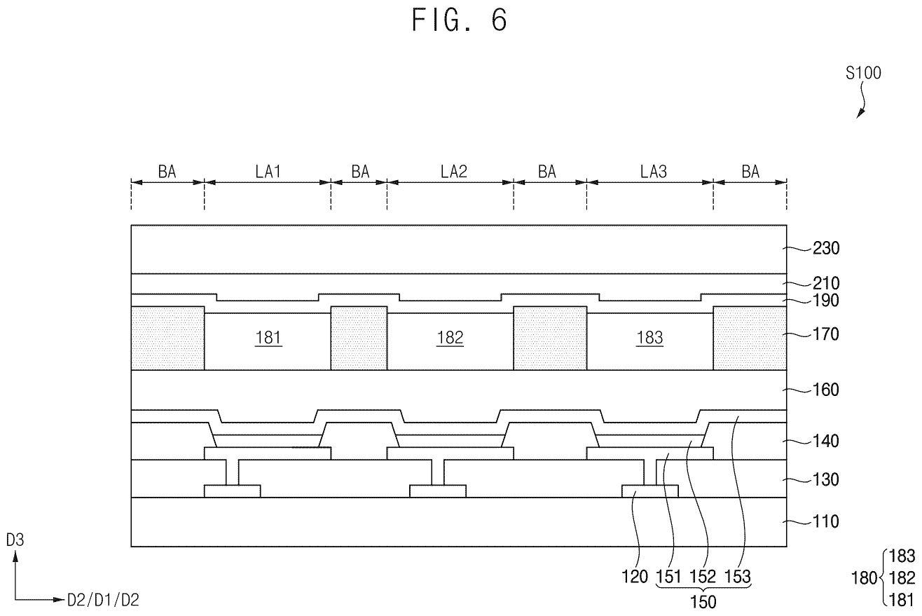

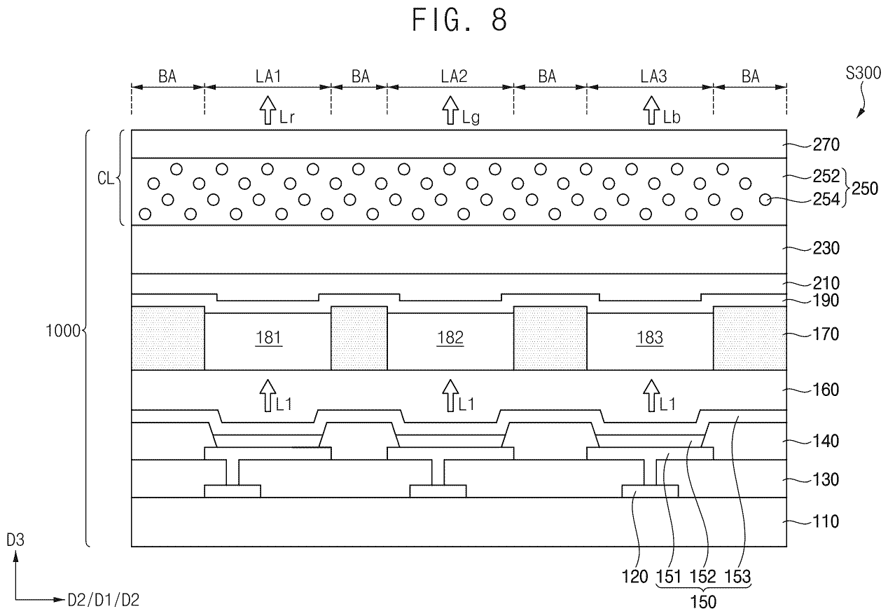

FIGS. 6, 7, and 8 are cross-sectional views illustrating a method of manufacturing the display device of FIG. 2.

Referring to FIG. 6, in an embodiment, the light-emitting device 150, the color conversion layer 180, and the color filter layer 230 may be sequentially formed on the substrate 110 (S100).

The substrate 110 including the transparent material or the opaque material may be provided. A driver 120 may be formed on the substrate 110. In an embodiment, the driver 120 may be formed using amorphous silicon, crystalline silicon, or metal oxide semiconductor, for example.

The insulating structure 130 may be formed on the substrate 110. The insulating structure 130 may be formed entirely in the first to third light-emitting areas LA1, LA2, and LA3 and the light-blocking area BA. The insulating structure 130 may cover the driver 120. In an embodiment, the insulating structure 130 may include at least one inorganic insulating layer and at least one organic insulating layer, for example.

The lower electrode 151 may be formed in each of the first to third light-emitting areas LA1, LA2, and LA3 on the insulating structure 130. The lower electrode 151 may be connected to the driver 120 through the contact hole defined by removing the portion of the insulating structure 130. In an embodiment, the lower electrode 151 may be formed using metal, alloy, metal nitride, conductive metal oxide, transparent conductive material, or the like, for example.

The pixel defining layer 140 may be formed in the light-blocking area BA on the insulating structure 130 and the lower electrode 151. The pixel defining layer 140 may have the opening that exposes the portion of the upper surface of the lower electrode 151. In an embodiment, the pixel defining layer 140 may be formed using the organic material or the inorganic material, for example.

The light-emitting layer 152 may be formed on the lower electrode 151. Specifically, the light-emitting layer 152 may be formed inside the opening of the pixel defining layer 140. In an embodiment, the light-emitting layer 152 may be formed using a relatively low molecular weight organic compound or a relatively high molecular weight organic compound, for example.

The upper electrode 153 may be formed on the light-emitting layer 152 and the pixel defining layer 140. The upper electrode 153 may be formed entirely in the first to third light-emitting areas LA1, LA2, and LA3 and the light-blocking area BA. In an embodiment, the upper electrode 153 may be formed using metal, alloy, metal nitride, conductive metal oxide, transparent conductive material, or the like, for example.

Accordingly, the light-emitting device 150 including the lower electrode 151, the light-emitting layer 152, and the upper electrode 153 may be formed in each of the first to third light-emitting areas LA1, LA2, and LA3 on the substrate 110.

The encapsulation structure 160 may be formed on the upper electrode 153. The encapsulation structure 160 may be formed entirely in the first to third light-emitting areas LA1, LA2, and LA3 and the light-blocking area BA. In an embodiment, the encapsulation structure 160 may include at least one inorganic encapsulation layer and at least one organic encapsulation layer, for example.

The bank layer 170 may be formed on the encapsulation structure 160. Specifically, the bank layer 170 may be formed to overlap the light-blocking area BA. In an embodiment, the bank layer 170 may be formed using the organic material or the like, for example.

The opening may be defined in the bank layer 170. The opening may overlap each of the light-emitting areas (e.g., the first light-emitting area LA1, the second light-emitting area LA2, and the third light-emitting area LA3). The opening may accommodate the ink composition in the process of forming the color conversion layer 180.

The color conversion layer 180 may be formed through an inkjet process. As described above, the color conversion layer 180 may be formed by discharging the ink composition into the opening. The ink composition may be repeatedly discharged into the opening and may form the plurality of color conversion patterns (e.g., the first color conversion pattern 181, the second color conversion pattern 182, and the transmission pattern (also referred to as a third color conversion pattern) 183) by baking.

The capping layer 190 may be formed on the color conversion layer 180 and the bank layer 170. The capping layer 190 may be formed entirely in the first to third light-emitting areas LA1, LA2, and LA3 and the light-blocking area BA. In an embodiment, the capping layer 190 may be formed using silicon oxide, silicon nitride, silicon oxynitride, or the like, for example.

The low refractive index layer 210 may be formed on the capping layer 190. The low refractive index layer 210 may be formed entirely in the first to third light-emitting areas LA1, LA2, and LA3 and the light-blocking area BA. In an embodiment, the low refractive index layer 210 may be formed using the organic material, for example.

The color filter layer 230 may be formed on the low refractive index layer 210. In an embodiment, the light-blocking pattern may first be formed on the low refractive index layer 210, for example. The light-blocking pattern may provide the space to accommodate the ink composition.

The color filter pattern may be formed by discharging the ink composition into the opening defined by the light-blocking pattern. The color filter pattern may be formed by discharging the ink composition into the space defined by the light-blocking pattern. By repeatedly discharging and baking the ink composition in the space, the plurality of color filter patterns (e.g., the first color filter pattern, the second color filter pattern, and the third color filter pattern) may be formed.

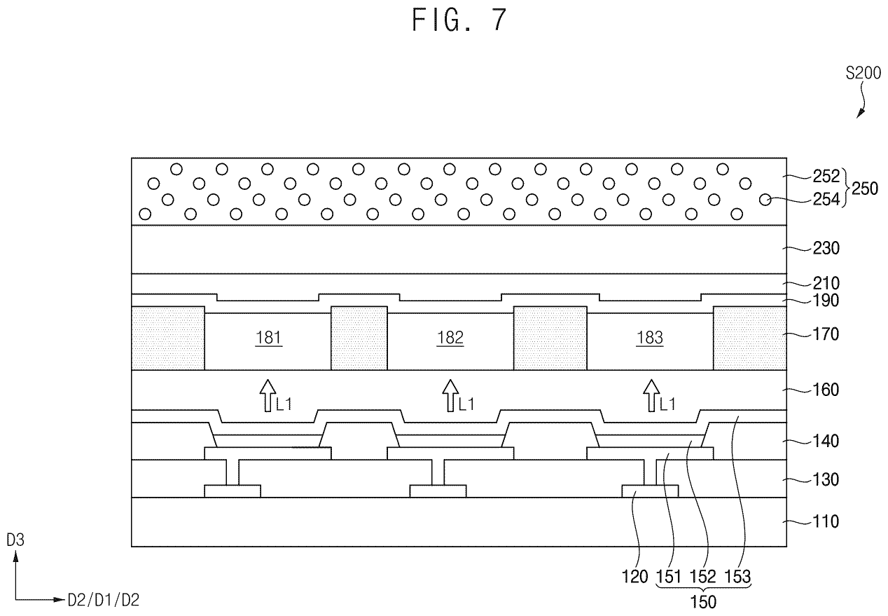

Referring to FIG. 7, in an embodiment, the first coating layer 250 may be formed on the color filter layer 230 (S200). The first coating layer 250 may be formed entirely on the first to third light-emitting areas LA1, LA2, and LA3 and the light-blocking area BA.

In an embodiment, the first coating layer 250 may include the dispersion layer 252 and the scattering particle 254. The scattering particle 254 may be dispersed in the dispersion layer 252. In an embodiment, the first coating layer 250 may be formed by mixing the scattering particles 254 with a material forming the dispersion layer 252, coating the mixing material on the color filter layer 230, and exposing the material, for example. A bake process may be further included between the coating and the exposing. The bake process may be a process to remove solvent.

In an embodiment, the dispersion layer 252 may include or consist of the inorganic material and/or the organic material. In an embodiment, the dispersion layer 252 may include or consist of acrylic resin, methacrylic resin, vinyl resin, epoxy resin, urethane resin, cellulose resin, perylene resin, silsesquioxane resin (e.g., POSS), or the like, for example. These may be used alone or in any combinations with each other. That is, the dispersion layer 252 may include or consist of the thermosetting material or the photocuring material. However, the disclosure is not limited thereto.

The scattering particle 254 may have the different refractive index from the material included in the scattering layer 252 and may include or consist of the particle capable of scattering the light. In an embodiment, the scattering particle 254 may be silica particles, hollow silica particles, organic polymer particles, metal oxide particles, metal particles, carbon particles, zeolite particles, or the like. These may be used alone or in any combinations with each other. However, the disclosure is not limited thereto.

The size S1 of the scattering particle 254 may be about ¼ or more of the wavelength of light. In an embodiment, the size S1 of the scattering particle 254 may be greater than or equal to about 0.2 micrometers (um) and less than or equal to about 2 micrometers (um).

When the size of the scattering particle 254 is less than about 0.2 micrometers, the scattering reflection may be difficult.

When the size of the scattering particle 254 exceeds about 2 micrometers, the thickness of the dispersion layer 252 that disperses the scattering particle 254 may become thick. Accordingly, the thickness of the display device 1000 may also increase.

In an embodiment, the content of the scattering particle 254 may be about 10 weight percent (wt. %) or more and about 80 weight percent (wt. %) or less.

When the amount of the scattering particle 254 is less than about 10 weight percent, the scattering reflection may be difficult.

When the content of the scattering particle 254 exceeds about 80 weight percent, the scattering particle 254 may be difficult to disperse in the dispersion layer 252. Accordingly, the film characteristic of the first coating layer 250 might not be realized.

In an embodiment, the thickness T1 of the first coating layer 250 may be about 3 micrometers or more and about 10 micrometers or less. Accordingly, the scattering particle 254 may be evenly dispersed in the dispersion layer 252.

In the above, it has been described that the first coating layer 250 includes or consists of the photocuring material in which the scattering particles 254 are dispersed, however the disclosure is not limited thereto. In an embodiment, the first coating layer 250 may include or consist of the thermosetting material, for example.

Referring to FIG. 12, in an embodiment, the second coating layer 270 having the smaller refractive index than a refractive index of the first coating layer 250 may be formed on the first coating layer 250 (S300). The second coating layer 270 may be formed entirely on the first to third light-emitting areas LA1, LA2, and LA3 and the light-blocking area BA. The second coating layer 270 may remove the specular reflected light through the destructive interference.

In an embodiment, the second coating layer 270 may include or consist of the silicon compound having the refractive index of less than about 1.5. Preferably, the second coating layer 270 may include or consist of the silicon compound having the refractive index of about 1.45 or less. In an embodiment, the second coating layer 270 may include or consist of silicon oxide, silicon nitride, silicon oxynitride, or the like, for example. These may be used alone or in any combinations with each other.

In an embodiment, the second coating layer 270 including the silicon compound may be formed through the chemical vapor deposition (“CVD”) process, for example. At this time, the refractive index may be adjusted by forming the porous in the second coating layer 270.

In an embodiment, the second coating layer 270 may include the polymer with the fluorine content of about 10% or more and the molecular weight of about 10,000 or more. In an embodiment, the second coating layer 270 may include the organic material substituted with fluorine and/or the inorganic material substituted with fluorine, for example. In an embodiment, the second coating layer 270 may include fluorinated-polysiloxane, fluorinated-polyurethane, fluorinated-polyurethane-acrylate, fluorinated polyhedral oligomer silsesquioxane, or the like, for example. These may be used alone or in any combinations with each other.

In an embodiment, as described above with reference to FIG. 5, the second coating layer 270 may further include the plurality of hollow inorganic particles (e.g., the inorganic particles 272′) dispersed therein. In an embodiment, each of the inorganic particles may include silica (SiO₂), magnesium fluoride (MgF₂), iron oxide (Fe₃O₄), or the like, for example. These may be used alone or in any combinations with each other.

In an embodiment, the second coating layer 270 may include the polymer with the content of inorganic particles of about 10 weight percent or more and about 80 weight percent or less and the molecular weight of about 10,000 or more.

In an embodiment, the size of the inorganic particles (e.g., the size of inorganic particles 272′) included in the second coating layer 270 may be about 50 nanometers or more and about 400 nanometers or less. The thickness T2 may be about 80 nanometers (nm) or more and about 500 nanometers (nm) or less.

Accordingly, the display device 1000 of FIG. 2 may be manufactured. In the above, it has been described that the second coating layer 270 includes or consists of the photocuring material, however the disclosure is not limited thereto. In an embodiment, the second coating layer 270 may include or consist of the thermosetting material, for example.

In the case of the display device according to the comparative example, the matte film may be attached on the display panel. The matte film may be attached to the display panel using the adhesive (e.g., the PSA, or the like). In the case of the matte film, the manufacturing cost is more than twice that of the “AR” film. Accordingly, the process cost of the display device according to the comparative example including the matte film may be high.

However, the method of manufacturing the display device in an embodiment of the disclosure may include forming the light-emitting device 150, the color conversion layer 180, and the color filter layer 230 on the substrate 110 sequentially (S100), forming the first coating layer 250 including the scattering particle 254 and the dispersion layer 252 in which the scattering particle 254 is dispersed on the color filter layer 230, and forming the second coating layer 270 having the smaller refractive index than a refractive index of the first coating layer 250 on the first coating layer 250. By forming the coating layers (e.g., the first coating layer 250 and the second coating layer 270), the process of manufacturing the display device may be simplified and the manufacturing cost may be reduced compared to the process of attaching additional member (e.g., the matte film).

SCI reflectance and SCE reflectance of the display device (e.g., the display device 1000 of FIG. 2) in embodiments of the disclosure were measured. The reflectance was measured using a CA-3700 reflectance measurement device. Here, the SCI reflectance represents a reflectance including scattered reflection and specular reflection, and the SCE reflectance represents a reflectance including only the scattered reflection. The SCI reflectance of the display device was about 3% or less, and the SCE reflectance was about 0.6% or more. Through these results, it may be confirmed that the reflectance due to the external light of the display device may be reduced.

In addition, pencil hardness of the display device was measured. The pencil hardness was measured using a pencil hardness tester. The pencil hardness was confirmed to be about 2H or more. Through these results, it may be confirmed that a surface hardness of the display device may be improved and external deformation may be prevented.

In addition, contact angle of the display device was measured. The contact angle was measured using a contact angle meter. The contact angle may be confirmed to be about 100 degrees or more. Through these results, it may be confirmed that the display device has an excellent antifouling property (e.g., a degree to which a fingerprint or a contaminant is easy to wipe off when the fingerprint or the contaminant adhere to the surface of the display device).

In addition, as described above, the manufacturing cost of the display device may be reduced by omitting the additional matte film by performing surface treatment on the display panel.

Embodiments of the invention may be applied to a display device and an electronic device including the display device such as computers, notebooks, cell phones, smart phones, smart pads, PMPs, PDAs, MP3 players, and/or the like, for example.

Embodiments of the disclosure should not be construed as being limited to the embodiments set forth herein. Rather, these embodiments are provided so that this disclosure will be thorough and complete and will fully convey the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims. Moreover, the embodiments or parts of the embodiments may be combined in whole or in part without departing from the scope of the invention.

What is claimed is:

1. A display device comprising:
a substrate;
a light-emitting device disposed on the substrate;
a color conversion layer disposed on the light-emitting device;
a color filter layer disposed on the color conversion layer;
a first coating layer disposed on the color filter layer and including a scattering particle and a dispersion layer in which the scattering particle is dispersed; and
a second coating layer disposed on the first coating layer and having a smaller refractive index than a refractive index of the first coating layer.

2. The display device of claim 1, wherein a refractive index of the scattering particle is different from a refractive index of the dispersion layer.

3. The display device of claim 2, wherein the scattering particle includes at least one of a silica particle, a hollow silica particle, an organic polymer particle, a metal oxide particle, a metal particle, a carbon particle, and a zeolite particle.

4. The display device of claim 1, wherein the scattering particle has a size of about 0.2 micrometers or more and about 2 micrometers or less.

5. The display device of claim 1, wherein a content of the scattering particle is about 10 weight percent or more and about 80 weight percent of less.

6. The display device of claim 1, wherein the second coating layer includes a silicon compound having the refractive index of less than about 1.5.

7. The display device of claim 1, wherein the second coating layer includes a material having a fluorine content of about 10 percent or more and a molecular weight of about 10,000 or more.

8. The display device of claim 1, wherein the second coating layer includes a material having a hollow silica content of about 10 weight percent or more and about 80 weight percent or less, and a molecular weight of about 10,000 or more.

9. The display device of claim 8, wherein a hollow silica particle of the hollow silica content has a size of about 50 nanometers or more and about 400 nanometers or less.

10. The display device of claim 1, wherein a thickness of the first coating layer is greater than a thickness of the second coating layer.

11. The display device of claim 1, wherein the second coating layer has a thickness of about 80 nanometers or more and about 500 nanometers or less.

12. The display device of claim 1, wherein the scattering particle scatters and reflects specularly reflected light.

13. The display device of claim 1, wherein the second coating layer destructively interferes with specularly reflected light.

14. A method of manufacturing a display device, the method comprising:
forming a light-emitting device, a color conversion layer, and a color filter layer on a substrate sequentially;
forming a first coating layer including a scattering particle and a dispersion layer in which the scattering particle is dispersed on the color filter layer; and
forming a second coating layer having a smaller refractive index than a refractive index of the first coating layer on the first coating layer.

15. The display device of claim 11, wherein the scattering particle is formed to have a size of about 0.2 micrometers or more and about 2 micrometers or less.

16. The display device of claim 11, wherein a content of the scattering particle is about 10 weight percent or more and about 80 weight percent of less.

17. The display device of claim 11, wherein the second coating layer includes a silicon compound having the refractive index of less than about 1.5.

18. The display device of claim 11, wherein the second coating layer includes a material having a fluorine content of about 10 percent or more and a molecular weight of about 10,000 or more.

19. The display device of claim 11, wherein the second coating layer includes a material having a hollow silica content of about 10 weight percent or more and about 80 weight percent or less, and a molecular weight of about 10,000 or more.

20. The display device of claim 11, wherein the second coating layer has a thickness of about 80 nanometers or more and about 500 nanometers or less.
